(19) United States
(12) Patent Application Publication
(10) Pub. No.: US 2013/0125969 A1
(43) Pub. Date: May 23, 2013

(54) PHOTOVOLTAIC DEVICES AND METHODS OF FORMING THE SAME

(71) Applicants: Wilhelmus A. de Groot, Palo Alto, CA (US); Sijin Han, Milpitas, CA (US); Fan Yang, Sunnyvale, CA (US)

(72) Inventors: Wilhelmus A. de Groot, Palo Alto, CA (US); Sijin Han, Milpitas, CA (US); Fan Yang, Sunnyvale, CA (US)

(73) Assignee: QUALCOMM MEMS Technologies, Inc., San Diego, CA (US)

(21) Appl. No.: 13/299,802

(22) Filed: Nov. 18, 2011

(51) Int. Cl. H01L 31/0232; H01L 31/0264; H01L 31/18; H01L 31/0224

(52) U.S. Cl. 136/256; 136/259; 136/258; 136/260; 136/261; 136/262; 438/71; 257/E31.13

(57) ABSTRACT

This disclosure provides photovoltaic apparatus and methods of forming the same. In one implementation, a method of forming a photovoltaic device includes forming a plurality of substrate features on a surface of a glass substrate, the substrate features having a depth dimension in the range of about 10 μm to about 1000 μm and a width dimension in the range of about 10 μm to about 1000 μm. The method further includes forming a thin film solar cell over the surface of the glass substrate including over the plurality of substrate features.

### TECHNICAL FIELD

This disclosure relates to photovoltaic devices.

### DESCRIPTION OF THE RELATED TECHNOLOGY

For over a century, hydrocarbon fuels including fossil fuels, such as coal, oil, and natural gas have provided the main source of energy in the United States. The need for alternative sources of energy is increasing. Fossil fuels are a non-renewable source of energy that is depleting rapidly. The large scale industrialization of developing nations such as India and China has placed a considerable burden on available fossil fuel. In addition, geopolitical issues can quickly affect the supply of such fuel. Global warming is also of greater concern in recent years. A number of factors are thought to contribute to global warming. For example, widespread use of fossil fuels is presumed to be a major contributor to global warming. Thus, there is a need to find a renewable and economically viable source of energy that is also environmentally safe. Solar energy is an environmentally safe renewable source of energy that can be converted into other forms of energy such as heat and electricity.

Photovoltaic cells convert optical energy to electrical energy and thus can be used to convert solar energy into electrical power. Photovoltaic cells can be made very thin and modular, and can range in size from about a few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Additionally, photovoltaic cells can be used in a wide range of applications, such as providing power to satellites and other spacecraft, providing electricity to residential and commercial properties, charging automobile batteries, and powering electronic devices, such as smart phones or personal computers.

While photovoltaic devices have the potential to reduce reliance upon hydrocarbon fuels, the widespread use of photovoltaic devices has been hindered by a variety of factors, including energy inefficiency. Accordingly, there is a need for photovoltaic devices having improved efficiency.

### SUMMARY

The systems, methods and devices of the disclosure each have several innovative aspects, no single one of which is solely responsible for the desirable attributes disclosed herein.

One innovative aspect of the subject matter described in this disclosure can be implemented in a photovoltaic device including a substrate including a first surface configured to receive light and a second surface opposite the first surface. The substrate includes a first plurality of substrate features formed on the second surface of the substrate, the first plurality of features having a depth dimension in the range of about 10 μm to about 1000 μm and a width dimension in the range of about 10 μm to about 1000 μm. The photovoltaic device further includes a first electrode formed on the first plurality of substrate features, a thin film solar cell disposed on the first electrode layer, and a second electrode formed on the thin film solar cell. At least a portion of the shape of the first electrode, the thin film solar cell, and the second electrode conform to the shape of the first plurality of substrate features.

In some implementations, the second surface of the substrate includes a second plurality of substrate features having a width dimension in the range of about 1 nm to about 100 nm and a depth dimension of about 1 to about 100 nm.

In some implementations, the shape of the second electrode at least partially conforming to the shape of the first plurality of substrate features such that at least a portion of incident light that reflects from the second electrode propagates through the thin film solar cell at least twice.

Another innovative aspect of the subject matter described in this disclosure can be implemented in a photovoltaic device including a substrate including a first surface configured to receive light and a second surface opposite the first surface. The substrate includes first means for reflecting light formed on the second surface, the first reflecting means having a depth dimension in the range of 10 μm to 1000 μm and a width dimension in the range of 10 μm to 1000 μm. The photovoltaic device further includes a first electrode formed on the first reflecting means, a thin film solar cell disposed on the first electrode layer, and a second electrode formed on the thin film solar cell. At least a portion of the first electrode, the thin film solar cell, and the second electrode conform to the shape of the first plurality of substrate features.

Another innovative aspect of the subject matter described in this disclosure can be implemented in a method of forming a photovoltaic device. The method includes forming a plurality of substrate features on a surface of a glass substrate, the substrate features having a depth dimension in the range of about 10 μm to about 1000 μm and a width dimension in the range of about 10 μm to about 1000 μm. The method further includes forming a thin film solar cell over the surface of the glass substrate including over the plurality of substrate features.

In some implementations, forming the plurality of substrate features includes etching the plurality of substrate features into the substrate using sand blasting.

In some implementations, forming the plurality of substrate features includes partially forming through-glass vias.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a photovoltaic device providing power to a load.

FIGS. 2A-2E show examples of cross-sectional schematic illustrations of various stages in methods of making photovoltaic devices of higher efficiency.

FIG. 3 shows an example of one implementation of a photovoltaic device.

FIGS. 4A-4H show examples of schematic plan view illustrations of glass substrates including substrate features.

FIGS. 5A and 5B show examples of schematic perspective view illustrations of glass substrates including substrate features.

FIGS. 6A-6D show examples of cross-sectional schematic illustrations of glass substrates including substrate features.

FIG. 7 shows an example of a cross-sectional schematic illustration of a multi-layer glass substrate including vias that extend either through the substrate or partially through the substrate.

FIG. 8 shows an example of a schematic perspective view illustration of a glass substrate including substrate features.

FIG. 9 shows an example of a flow diagram illustrating a manufacturing process for a photovoltaic device.

### DETAILED DESCRIPTION

In some implementations described herein, photovoltaic devices including a substrate, such as a glass substrate, and a thin film solar cell are disclosed. The glass substrate can have a first surface for receiving light and a second surface including substrate features over which the thin film solar cell is formed. The geometry of the substrate features can be designed to capture reflected light by configuring substrate features to include sloped sides for directing reflected light towards other portions of the thin film solar cell. The geometry of the substrate features can also increase the optical path length of light through the solar cell. The substrate features can have a depth dimension in the range of about 10 μm to about 1000 μm and a width dimension in the range of about 10 μm to about 1000 μm, and in some implementations, the substrate features can be formed using a through-glass via process. The first surface of the glass substrate can also be configured to operate as a boundary for total internal reflection (TIR) of a portion of light reflected off of the thin film solar cell, thus improving the efficiency of the photovoltaic device by reducing the amount of light escaping the photovoltaic device through reflections. In some implementations, the surface of the substrate features can be roughened to include features having a width dimension in the range of about 1 nm to about 100 nm. The roughened surface can help diffuse light incident on the solar cell, which can improve efficiency of the photovoltaic device by reducing the amount of light that escapes the photovoltaic device without being absorbed by the solar cell.

Implementations of the subject matter described in this disclosure can increase power efficiency of a photovoltaic device, thereby increasing the magnitude of a photocurrent generated from a given amount of light. Additionally, some implementations can be used to increase the optical path length of light through a solar cell so as to increase the probability that the light is absorbed by the solar cell without needing to increase electrical thickness. For example, certain implementations increase the angle of incidence of light reaching the solar cell, thereby increasing the distance light travels through the solar cell while avoiding electrical losses associated with increasing the physical thickness of the solar cell, such as recombination losses associated with charge carriers of opposite polarity recombining. Furthermore, some implementations can be used to reduce the amount of light that is reflected off of a photovoltaic device.

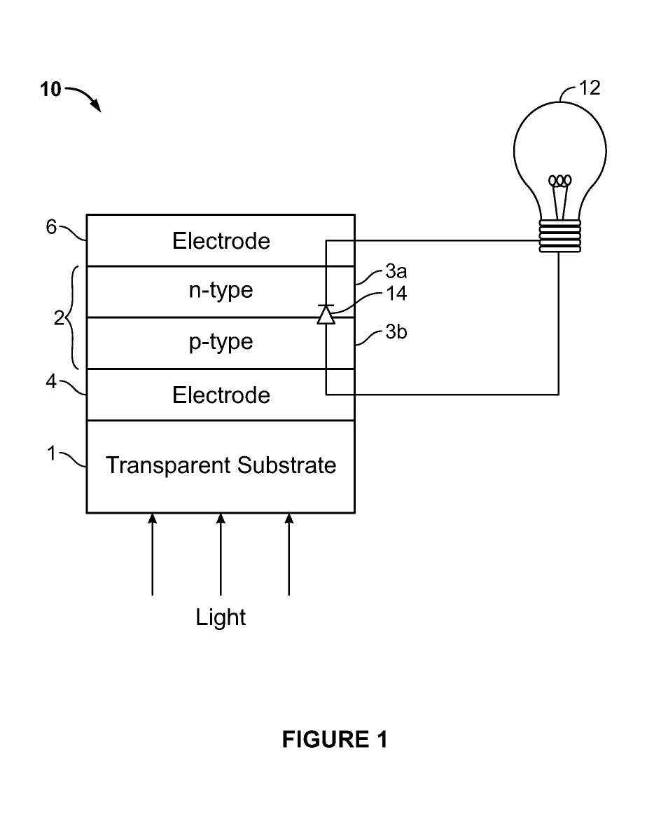

FIG. 1 shows an example of a photovoltaic device 10 providing power to a load 12. The photovoltaic device 10 includes a transparent substrate 1, a solar cell 2, a first electrode 4, and a second electrode 6. The first electrode 4 is formed over the transparent substrate 1, the solar cell 2 is formed over the first electrode 4, and the second electrode 6 is formed over the solar cell 2. In some implementations, the solar cell 2 includes an n-type photovoltaic layer 3a and a p-type photovoltaic layer 3b. In the illustrated configuration, the p-type photovoltaic layer 3b is disposed between the first electrode 4 and the n-type photovoltaic layer 3a, and the n-type photovoltaic layer 3a is disposed between the p-type photovoltaic layer 3b and the second electrode 6. However, other implementations are possible, such as a configuration in which the order of the n-type photovoltaic layer 3a and the p-type photovoltaic layer 3b is reversed. Additionally, in some implementations an intrinsic layer can be disposed between the n-type photovoltaic layer 3a and the p-type photovoltaic layer 3b so as to form a p-i-n junction solar cell.

The transparent substrate 1 can be a glass substrate or any other suitable transparent substrate, such as an optical plastic. The transparent substrate 1 can be employed to structurally support the first and second electrodes 4 and 6 and the solar cell 2. The transparent substrate 1 includes a first surface configured to receive light, and a second surface over which the first electrode 4, the solar cell 2, and the second electrode 6 are formed.

The first and second electrodes 4 and 6 can be any suitable conductor. In some implementations, the first electrode 4 can include a transparent conductor, such as a transparent conducting oxide (TCO). Using a TCO or other transparent conductor for the first electrode 4 can provide electrical connectivity to the solar cell 2, while permitting light to pass through the first electrode 4 and reach the solar cell 2. However, the first electrode 4 need not be transparent, such as in configurations in which the first electrode 4 is formed of an opaque material and includes one or more openings that provide a path for light to reach the solar cell 2. In certain implementations, the second electrode 6 is formed from an opaque material, such as a reflector configured to reflect light back toward the solar cell 2. However, other configurations are possible.

Although not illustrated in FIG. 1, in some configurations the photovoltaic device 10 can include an antireflective structure for reducing the amount of light reflected off of the photovoltaic device 10. For example, the photovoltaic device 10 can include an antireflective coating disposed on the first surface of the transparent substrate 1 configured to receive light. The antireflective structure can reduce the amount of light reflected off of the photovoltaic device 10, thereby increasing the amount of light reaching the solar cell 2 and the overall power efficiency of the device.

The solar cell 2 can be formed from a wide variety of materials, including, for example, silicon (Si), germanium (Ge), cadmium telluride (CdTe), copper indium gallium (di)selenide (CIGS), III-V semiconductors, and/or organics such as light absorbing small molecular weight dyes and polymers. The solar cell 2 can operate as a photodiode 14, which can convert light energy into electrical energy or current. When the photovoltaic device 10 is illuminated with light, photons from the light can transfer energy to the solar cell 2, which can result in the creation of electron-hole pairs. For example, photons having energy greater than the band-gap of the material(s) in the solar cell 2 can generate electron-hole pairs within the solar cell 2 by band-to-band excitation. In addition, high-energy photons can generate electron-hole pairs by impact ionization or via recombination-generation centers within the lattice of the solar cell 2.

When photons create electron-hole pairs within or near a depletion region of the solar cell 2, the electric field of the depletion region can sweep the electrons and holes to the first and second electrodes 4 and 6 of the photovoltaic device 10, thereby generating a photocurrent. The electron-hole pairs can also move via diffusion through the photovoltaic device 10. The generated photocurrent can be used to provide power to a load 12, which can be, for example, a load associated with a solar panel.

The optical path length of light through the solar cell 2 can impact the efficiency of the photovoltaic device 10. For example, if the optical path length through the solar cell 2 is relatively long, the probability that light is absorbed by the solar cell 2 can increase. However, increasing the optical path length of light through the solar cell 2 using certain techniques, such as increasing the thickness of the n-type and/or p-type photovoltaic layers 3a and 3b (or an intrinsic layer in p-i-n junction configurations) can increase recombination losses associated with the solar cell 2 and degrade performance. Light reflections can also impact the efficiency of the photovoltaic device 10. For example, the efficiency of the photovoltaic device 10 can be limited by light reflected off of the photovoltaic device 10, such as light reflected off the first electrode 4 and/or light reflected off the solar cell 2. Although antireflective coatings or other structures can be used to reduce reflections, there remains a need for improving the efficiency of the photovoltaic device 10.

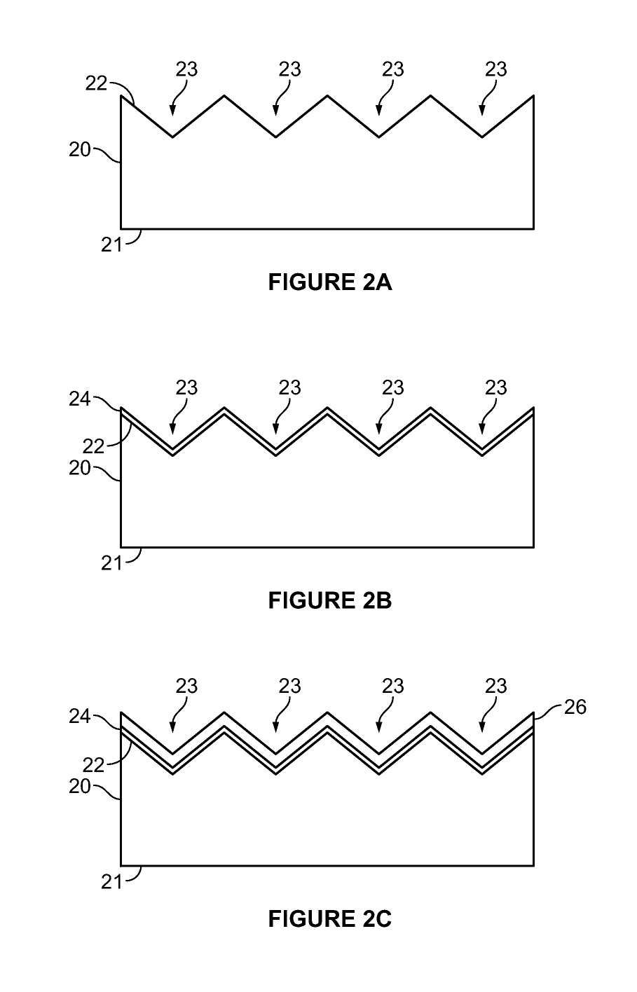

FIGS. 2A-2E show examples of cross-sectional schematic illustrations of various stages in methods of making photovoltaic devices of higher efficiency.

FIG. 2A illustrates forming substrate features 23 on a substrate 20. The substrate 20 includes a first surface 21 and a second surface 22 opposite the first surface 21. As illustrated in FIG. 2A, the substrate features 23 have been formed on the second surface 22 of the substrate 20. In some implementations, the substrate 20 is glass, or includes at least one glass layer. In other implementations, the substrate 20 can be acrylic, plastic, or another suitable transparent material. In the example implementations described herein, the substrate 20 is glass, and is accordingly referred to as a glass substrate 20.

In some implementations, the substrate features 23 can each have a depth selected to be in the range of about 10 μm to about 1000 μm and a width in the range of about 10 μm to about 1000 μm. In the configuration illustrated in FIG. 2A, the substrate features 23 are abutting. Accordingly, in some implementations, the substrate features 23 can be configured to have a relatively high density, including, for example, a density associated with a maximum fill factor permitted by a process used to form the substrate features 23, such as a fill factor greater than about 95%. However, as will be described in detail further below, in some implementations the substrate features 23 can be arranged in configurations in which the substrate features 23 do not abut.

The substrate features 23 can be formed on the second surface 22 of the glass substrate 20 using a variety of processes. For example, the substrate features 23 can be formed using sand blasting, laser blasting, and/or chemical etching. Although the substrate features 23 in the illustrated configuration do not extend through the glass substrate 20, in some implementations the substrate features 23 can be formed using a through-glass via process in which blasting or etching associated with the substrate features 23 is stopped before the substrate features 23 extend through the glass substrate 20. Accordingly, in some implementations the substrate features 23 can be partially-formed through-glass vias. For example, through-glass via processing can be performed to form a cavity in the second surface 22 and/or a relatively thick glass substrate can be used to prevent through-glass via formation, such as a glass substrate having a thickness in the range of about 200 μm to about 6 mm. Using a through-glass via process to form the substrate features 23 can reduce the cost of manufacturing the photovoltaic device.

In FIG. 2B, a first electrode 24 has been formed over the substrate features 23 of the substrate 20. The first electrode 24 can include a transparent conductor, including, for example, a transparent conducting oxide (TCO), such as tin oxide (SnO₂), zinc oxide (ZnO), indium tin oxide (ITO) and/or doped oxides, such as aluminum doped zinc oxide (AZO) or fluorine doped zinc oxide (ZnO:F). In some implementations, the first electrode 24 has a thickness selected to be in the range of about 5 nm to about 1000 nm.

FIG. 2C illustrates forming a solar cell 26 over the first electrode 24. The solar cell 26 can be formed using thin film techniques, such as deposition processes employing physical vapor deposition (PVD), chemical vapor deposition (CVD), electro-chemical vapor deposition (EVD) and/or plasma enhanced chemical vapor deposition (PE-CVD). As shown in FIG. 2C, the solar cell 26 can have a geometry conforming to the substrate features 23. As used herein, “thin film” generally refers to solar cells formed by depositing selected materials, and the thickness of the particular thin film solar cell depends on the material deposited. In some implementations, the solar cell 26 has a thickness in the range of about 0.1 μm to about 10 μm.

In some implementations, the thin film solar cell 26 can include amorphous, monocrystalline, or polycrystalline materials, including, for example, silicon, copper indium selenide (CIS), CdTe, CIGS, dye-sensitized or other organic photovoltaics. In some implementations, the solar cell 26 is a thin film p-i-n junction solar cell.

In FIG. 2D, a second electrode 28 has been formed over the solar cell 26. In some implementations, the second electrode 28 can include a reflective layer, such as aluminum (Al) or silver (Ag). By including a reflective layer in the second electrode 28, the second electrode 28 can be used to reflect light that passes through the solar cell 26 back toward the solar cell 26, thereby increasing the probability that the light is absorbed in the photovoltaic device. In some implementations, the second electrode 28 has a thickness selected to be in the range of about 10 nm to about 1 mm.

FIG. 2E illustrates a photovoltaic device according to another implementation. The photovoltaic device of FIG. 2E is similar to the photovoltaic device of FIG. 2D, except that the second surface 22 of the glass substrate 20 is roughened.

Roughening one or more surfaces disposed between the first electrode 24 and the solar cell 26 can increase the diffusion of light within solar cell 26 and improve efficiency of the device. For example, roughening a surface of the first electrode 24 can diffuse light reaching the solar cell 26, thereby increasing the path length of light through the solar cell 26 and/or reducing the amount of light reflected off the photovoltaic device. In some implementations, a roughened surface disposed between the solar cell 26 and the first electrode 24 includes features having a width dimension in the range of about 1 nm to about 100 nm, and a depth dimension in the range of about 1 nm to about 100 nm.

Any suitable process can be used to roughen a surface between the solar cell 26 and the glass substrate 20. For example, in some implementations a surface of the first electrode 24 facing the solar cell 26 can be roughened using wet etch techniques or can be deposited with a rough surface by, for example, means of chemical vapor deposition (CVD) techniques. However, surface roughening can be achieved in other ways. For example, the first electrode 24 can be formed using a CVD process. Although FIG. 2E illustrates a roughened surface between the first electrode 24 and solar cell 26, in some implementations another surface can additionally or alternatively be roughened. For example, in some implementations the second surface 22 of the glass substrate 20 is roughened before forming the first electrode 24 using a dry etch, a wet etch, and/or by sand blasting.

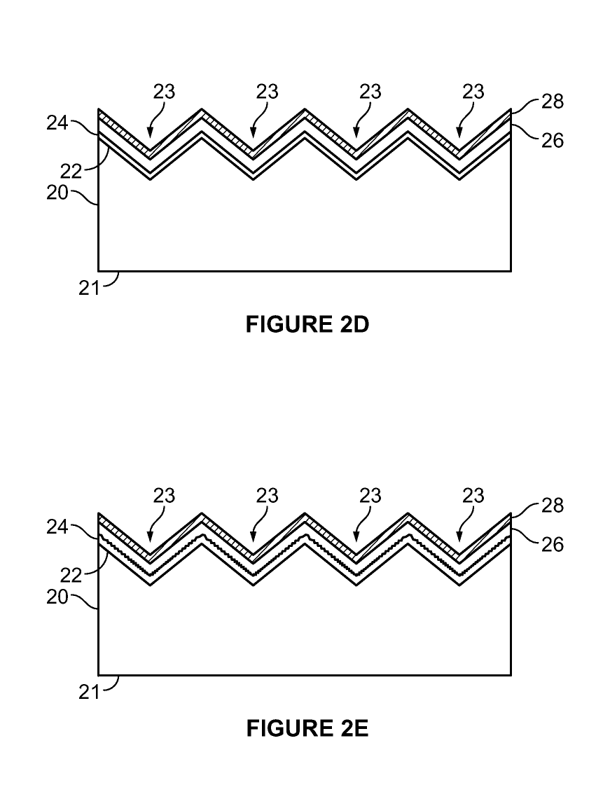

FIG. 3 shows an example of one implementation of a photovoltaic device 30. The photovoltaic device 30 includes a glass substrate 20 having a first surface 21 configured to receive light and a second surface 22 opposite the first surface 21. A plurality of substrate features, such as substrate features 23a-23d illustrated in FIG. 3, have been formed on the second surface 22 of the glass substrate 20. The photovoltaic device 30 further includes a first electrode 24 formed over the substrate features 23, a solar cell 26 formed over the first electrode 24, and a second electrode 28 formed over the solar cell 26. The photovoltaic device 30 can be made using the process described earlier with respect to FIGS. 2A-2E.

The photovoltaic device 30 can be configured to receive light through the first surface 21 of the glass substrate 20. For example, a first portion of light 32 normal to the first surface 21 of the glass substrate 20 can pass through the glass substrate 20 and reach the solar cell 26. As shown in FIG. 3, although the first portion of light 32 is normal to the first surface 21 of the glass substrate 20, the first portion of light 32 can have an angle of incidence less than ninety degrees with respect to the solar cell 26. For example, forming the solar cell 26 over the substrate features 23a-23d has resulted in the first portion of light 32 being angled with respect to the normal of the solar cell 26. By configuring the solar cell 26 to receive light at an angle, the optical path length of light through the solar cell 26 can be increased to improve carrier conversion efficiency, since the optical path length through the solar cell 26 for light reaching a solar cell at angled incidence can be longer relative to the optical path length for light reaching the solar cell 26 at a normal or 90 degree incidence. Increasing the optical path length of light by forming the solar cell 26 over the substrate features 23a-23d can offer improved performance relative to other schemes of increasing optical path length, such as increasing the electrical thickness of the solar cell 26, which can increase carrier recombination and degrade solar cell efficiency.

Forming the solar cell 26 over the substrate features 23a-23d can also improve the efficiency of the photovoltaic device 30 by increasing the amount of unabsorbed light that is reflected back toward the solar cell 26. For example, when the first portion of light 32 reaches a region of the solar cell 26 associated with the first substrate feature 23a, an unabsorbed portion of light 33 can be reflected off of the second electrode 28 toward a region of the solar cell 26 associated with the second substrate feature 23b. Thus, by shaping the second electrode 28 to at least partially conform to the shape of the substrate features 23a-23d, the unabsorbed portion of light 33 that reflects from the second electrode 28 propagates through the solar cell 26 at least twice.

The geometry of the substrate features 23a-23d helps improve the efficiency of the photovoltaic device 30 by reducing the amount of light that escapes the photovoltaic device 30 without being absorbed by the solar cell 26. For example, to reduce the probability that the first portion of light 32 reflects off the second electrode 28 and escapes the photovoltaic device 30 through the first surface 21 of the glass substrate 20, the side of the first substrate feature 23a has been sloped to direct the first portion of light 32 toward the second substrate feature 23b when it is unabsorbed. In one implementation, the substrate features 23a-23d have an angle of slope relative to the second surface 22 that is in the range of about 20 degrees to about 70 degrees. The slope of the substrate features 23a-23d can be selected based on a variety of considerations, including, for example, on the angular distribution of light reaching the photovoltaic device 30 under typical operating conditions. For example, in some implementations, the slope of the substrate features 23a-23d can be selected to increase the probability that light reaching the first surface 21 at the mean angle of incident is absorbed.

Forming the solar cell 26 over the substrate features 23a-23d can also result in a portion of reflected light undergoing total internal reflection in the glass substrate 20. For example, as shown in FIG. 3, a second portion of light 34 can propagate through the glass substrate 20 and can be reflected one or more times off the second electrode 28 between substrate features 23c and 23d before being directed back toward the first surface 21 of the glass substrate 20. The reflected light 35 can reach the first surface 21 of the glass substrate 20 and can undergo total internal reflection (TIR) to be reflected back toward the solar cell 26 as a totally internally reflected portion of light 36. Accordingly, including the substrate features 23a-23d can improve efficiency of the photovoltaic device 30 by increasing the amount of light captured in the glass substrate 20 through the waveguide effect, that otherwise would have been reflected back out of substrate 20 through the first surface 21.

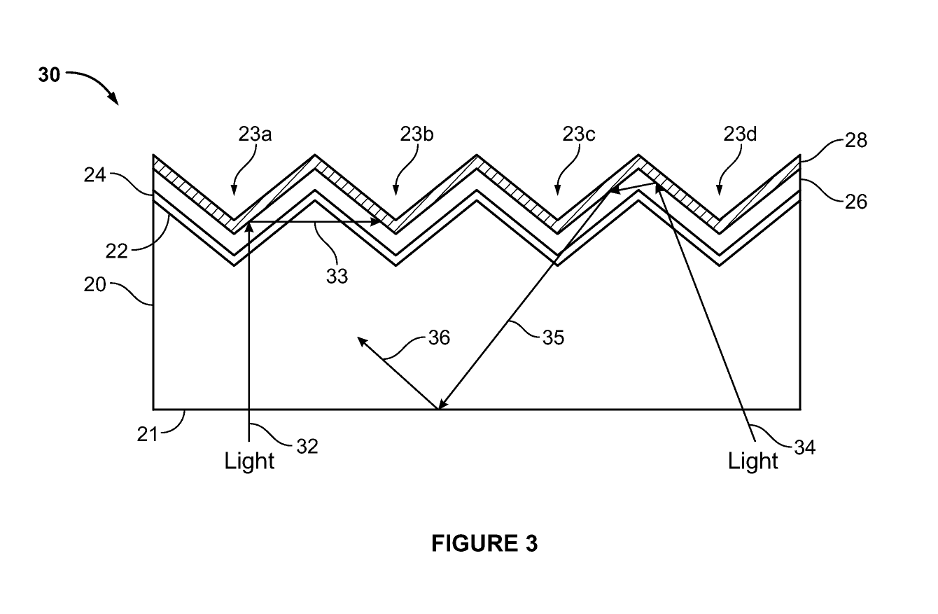

FIGS. 4A-4H show examples of schematic plan view illustrations of glass substrates including substrate features. The glass substrates can be used in the photovoltaic devices and processes described herein.

FIG. 4A illustrates an example of a glass substrate 50 including a plurality of substrate features 123 arranged in an array. In the illustrated configuration, the substrate features 123 each have a circular shape when viewed from above the glass substrate 50, and are separated by a distance d₁, which can be selected to be, for example, in the range of about 0 μm (abutting adjacent features 123) to about 1000 μm. In the illustrated configuration, the substrate features 123 are arranged in a square grid having a pitch d₂, which in some implementations is selected to be in the range of about 10 μm to about 1000 μm.

FIG. 4B illustrates another example of a glass substrate 51 including a plurality of substrate features 124 arranged in an array. In the illustrated configuration, the substrate features 124 each have a circular shape when viewed from above the glass substrate 51, and the substrate features 124 are arranged in a hexagonal grid. Although FIGS. 4A and 4B illustrate configurations in which the substrate features 124 are arranged in arrays, the substrate features 124 need not be arranged in an organized pattern, as will be described below.

FIG. 4C illustrates an example of a glass substrate 52 including a plurality of substrate features 125 arranged in an unorganized or random pattern. In the illustrated configuration, the features 125 have a circular shape when viewed from above the glass substrate 52. In contrast to the glass substrates 50 and 51 of FIGS. 4A and 4B that include substrate features 125 spaced substantially evenly apart and arranged in rows, the glass substrate 52 of FIG. 4C includes the substrate features 125 placed randomly thereon.

Although the glass substrates 50, 51 and 52 of FIGS. 4A-4C show implementations in which each feature is of a similar size and shape, in other configurations, multiple different feature sizes and/or shapes can be used.

FIG. 4D illustrates an example of a glass substrate 53 including a first plurality of substrate features 126a and a second plurality of substrate features 126b arranged in an array. For example, the first and second pluralities of substrate features 126a and 126b have been arranged in a square grid with the first and second pluralities of substrate features 126a and 126b positioned on alternating lattice points of the grid.

Still referring to FIG. 4D, in the illustrated configuration, the first and second pluralities of substrate features 126a and 126b each have a circular shape when viewed from above the glass substrate 53, but the first plurality of substrate features 126a have a larger size relative to the second plurality of substrate features 126b. In some implementations, each of the first plurality of substrate features 126a have a width that is about 1 times to about 10 times greater than the width of each of the second plurality of substrate features 126b. Using multiple features sizes can increase the fill factor of the substrate features in certain processes. In some implementations, the first and second pluralities of substrate features 126a and 126b have the same depth into the glass substrate 53. However, in other implementations, the first and second pluralities of substrate features 126a and 126b have different depths extending into the glass substrate 53. Note that in other implementations, the position of the first and second pluralities of substrate features 126a and 126b in the array can be reversed.

FIG. 4E illustrates another example of a glass substrate 54 including a first plurality of substrate features 127a and a second plurality of substrate features 127b arranged in an array. In the illustrated configuration, the first plurality of substrate features 127a has a square shape when viewed from above the glass substrate 54 and the second plurality of substrate features 127b has a circular shape. Additionally, the first plurality of substrate features 127a has a larger size relative to the second plurality of substrate features 127b.

FIG. 4F illustrates an example of a glass substrate 55 including a first plurality of substrate features 128a and a second plurality of substrate features 128b arranged in an unorganized pattern. In the illustrated configuration, the first and second pluralities of substrate features 128a and 128b each have a circular shape when viewed from above the glass substrate 55, but the first plurality of substrate features 128a have a larger size relative to the second plurality of substrate features 128b.

Although FIGS. 4A-4F show implementations in which the substrate features are circular shaped and/or square shaped when viewed from above the glass substrate, the substrate features can be configured to have other shapes, including, for example, shapes that are elliptical, hexagonal, or rectangular.

FIG. 4G illustrates another example of a glass substrate 56 including a plurality of substrate features 129 arranged in an array. In the illustrated configuration, the substrate features 129 each have a rectangular shape when viewed from above the glass substrate 56, and the substrate features 129 are arranged in a rectangular grid.

FIG. 4H illustrates another example of a glass substrate 57 including a plurality of substrate features 130 arranged in an array. In the illustrated configuration, the substrate features 130 each have a square shape when viewed from above the glass substrate 57, and the substrate features 130 are arranged in a square grid.

Although only eight examples of placement and organization of substrate features have been illustrated in FIGS. 4A-4H, one of ordinary skill in the art will readily recognize from the above description that other configurations can be designed using different combinations of substrate feature shapes, sizes, and/or arrangements, including, for example, implementations using more than two shapes or sizes of substrate features.

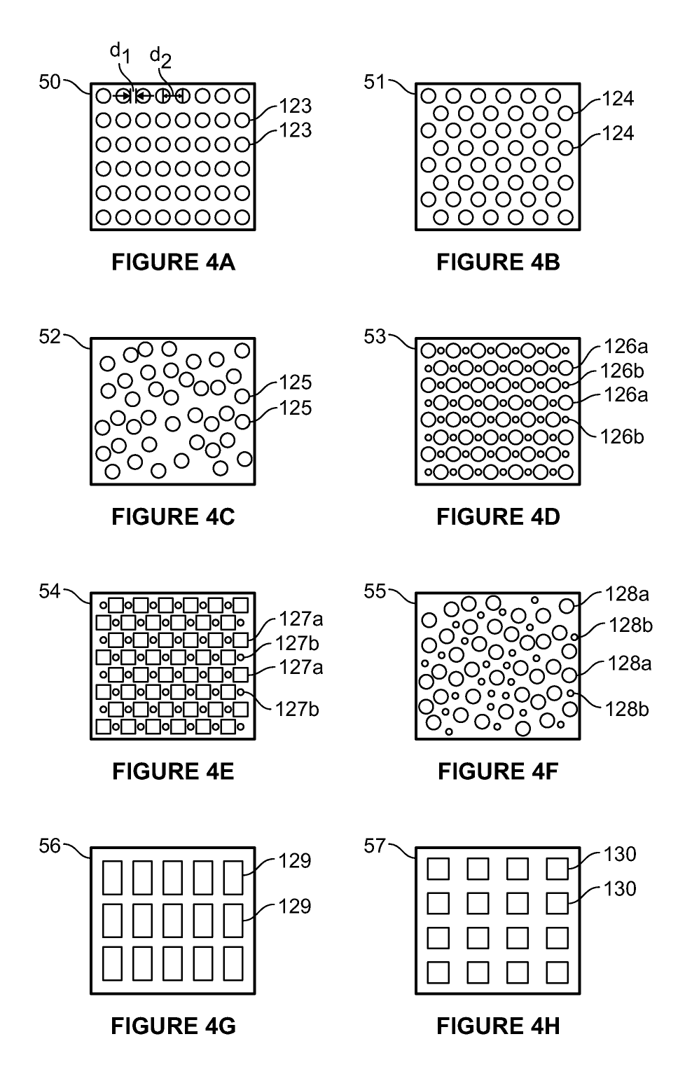

FIGS. 5A and 5B show examples of schematic perspective view illustrations of glass substrates including substrate features. The glass substrates can be used in the photovoltaic devices and processes described herein.

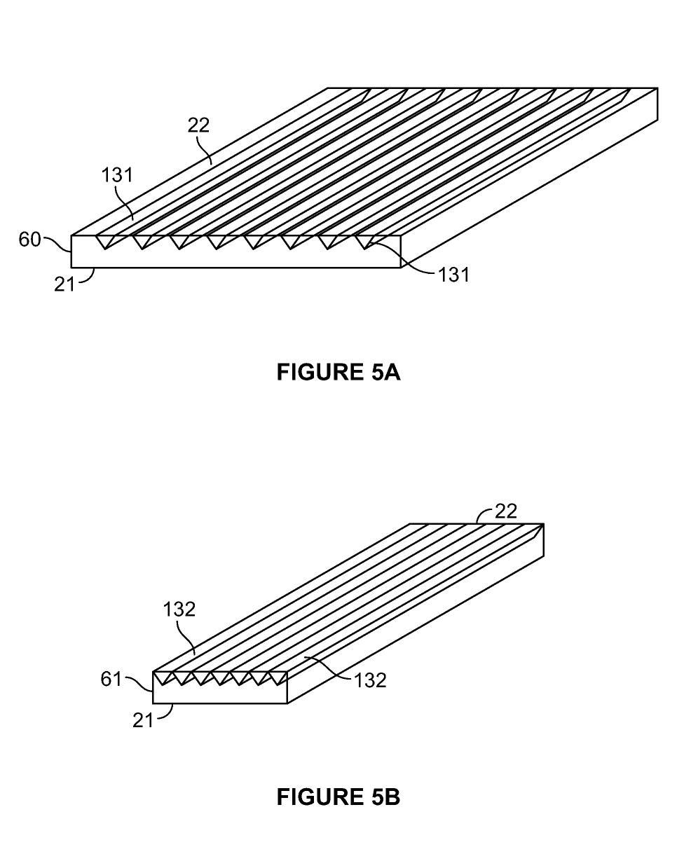

FIG. 5A illustrates an example of a glass substrate 60 including a plurality of substrate features 131 arranged as grooves. The glass substrate 60 includes a first surface 21 for receiving light and a second surface 22 on which the substrate features 131 have been formed. In the illustrated configuration, the substrate features 131 run the full length of the glass substrate 60. However, in some implementations, the substrate features 131 have a length less than that of the glass substrate 60. When arranged as grooves, the substrate features 131 can be separated by a distance selected to be in the range of about 0 μm (abutting) to about 3000 μm. Although the cross-section of the substrate features 131 is illustrated as being triangular, the cross-section of the substrate features 131 can have any suitable shape, including, for example, any of the cross-sectional shapes illustrated and described later below with reference to FIGS. 6A-6D.

FIG. 5B illustrates an example of a glass substrate 61 including a plurality of substrate features 132 arranged as grooves. The glass substrate 61 of FIG. 5B is similar to the glass substrate 60 of FIG. 5A, except that the glass substrate 61 of FIG. 5B illustrates a case in which the groove-shaped substrate features are abutting. Although only two examples of grooves have been illustrated in FIGS. 5A and 5B, other configurations can be used.

FIGS. 6A-6D show examples of cross-sectional schematic illustrations of glass substrates including substrate features. The glass substrates can be used in the photovoltaic devices and processes described herein.

FIG. 6A illustrates an example of a glass substrate 70 that includes a feature 133 having a triangular shaped cross-section. The glass substrate 70 includes a first surface 21 and a second surface 22 opposite the first surface 21, and the feature 133 is formed on the second surface 22 of the glass substrate 70. The feature 133 has a width x₁, a depth x₂, and an angle of slope θ relative to the second surface 22. In some implementations, the width x₁ is selected to be in the range of about 10 μm to about 1000 μm, the depth x₂ is selected to be in the range of about 10 μm to about 1000 μm, and the angle of slope θ is selected to be in the range of about 20 degrees to about 70 degrees.

FIG. 6B illustrates an example of a glass substrate 71 that includes a feature 134 having a trapezoidal-shaped cross-section. The glass substrate 71 includes a first surface 21 and a second surface 22 opposite the first surface 21, and the feature 134 is formed on the second surface 22 of the glass substrate 71. Additional details of the feature 134 of FIG. 6B can be similar to those described above with respect to FIG. 6A.

FIG. 6C illustrates an example of a glass substrate 72 that includes a feature 135 having a bowl-shaped or curved cross-section. The glass substrate 72 includes a first surface 21 and a second surface 22 opposite the first surface 21, and the feature 135 is formed on the second surface 22 of the glass substrate 72. Additional details of the feature 135 of FIG. 6C can be similar to those described above with respect to FIG. 6A.

FIG. 6D illustrates an example of a glass substrate 73 that includes a feature 136 having a trapezoidal-shaped cross-section with a curved bottom. The glass substrate 73 includes a first surface 21 and a second surface 22 opposite the first surface 21, and the feature 136 is formed on the second surface 22 of the glass substrate 73. In some implementations, the substrate feature 136 includes side walls having a slope selected to be in the range of about 20 degrees to about 70 degrees, and a bottom that curves in a direction toward the second surface 22 of the glass substrate 73, or a bottom that curves in any suitable curved shape. Additional details of the feature 136 of FIG. 6D can be similar to those described above with respect to FIG. 6A.

Although only four examples of substrate feature cross-sections have been illustrated in FIGS. 6A-6D, other substrate features can be used.

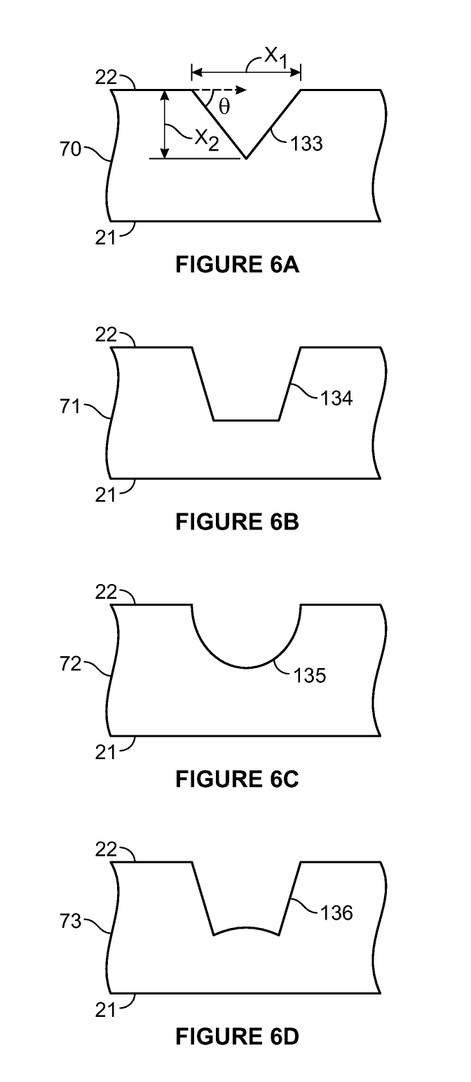

FIG. 7 shows an example of a cross-sectional schematic illustration of a multi-layer glass substrate including vias 83 that extend either through the glass substrate 80 or partially through the glass substrate 80. The vias 83 can be referred to as “through-glass vias” for convenience. However, such a reference is not meant to be limiting, and such vias can also be formed in a substrate made from a material other than glass. In addition, reference to a first glass layer 81 and a second glass layer 82 are for convenience of this disclosure and is not meant to limit such layers to be formed from glass. For example, such layers can also be formed from other suitable materials such as plastic, acrylic, or another suitable material that transmits light.

The multi-layer glass substrate 80 includes a first glass layer 81, a second glass layer 82, a first surface 21, and a second surface 22. A surface of the first glass layer 81 defines the first surface 21 of the multi-layer glass substrate 80, and a surface of the second glass layer 82 defines the second surface 22 of the multi-layer glass substrate 80. The through-glass vias 83 extend from the second surface 22 of the multi-layer glass substrate 80 through the first glass layer 81. The through-glass vias 83 can be formed using a sand blasting process, a chemical etching process, a laser blasting process, and/or another suitable through-glass via process.

The second glass layer 82 can provide support to the first glass layer 81, and can aid in forming part of a support structure over which a solar cell structure can be formed. For example, a first electrode can be deposited over the second surface 22 of the multi-layer glass substrate 80 and can contact portions of the first and second glass layers 81, 82. Then a thin film solar cell can be deposited over the first electrode, followed by a second electrode. Details of some implementations of manufacturing a photovoltaic device on a glass substrate have been discussed above.

The first glass layer 81 can be attached to the second glass layer 82 in a variety of ways. For example, in some implementations the first glass layer 81 is attached to the second glass layer 82 using optically matching glues or fluids.

Although FIG. 7 illustrates a configuration using a multi-layer glass substrate 80 including a first glass layer 81 having through-glass vias 83, in some implementations described herein single layer substrates are provided that include partially-formed through-glass vias. For example, in some implementations, partially-formed through-glass vias can be formed in a glass substrate by stopping blasting or etching processes before through-glass via structures are formed. In some implementations, through-glass via processes can be used to form the photovoltaic device discussed above. For example, in some implementations, the photovoltaic devices of FIGS. 2A-6D can be manufactured using through-glass via processes in which partially-formed through-glass vias are formed on a substrate.

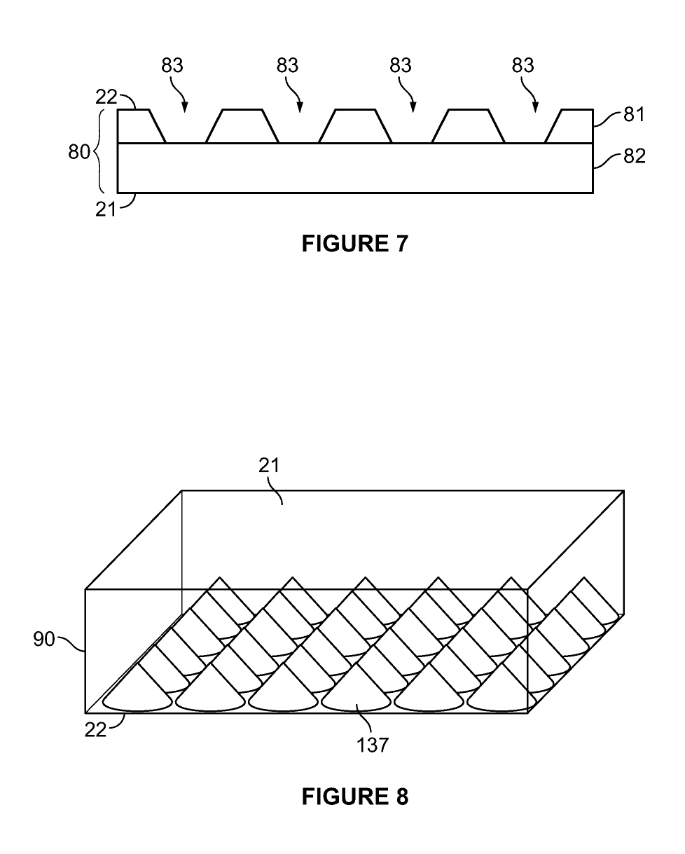

FIG. 8 shows an example of a schematic perspective view illustration of a glass substrate 90 including substrate features 137. The glass substrate 90 includes a first surface 21 for receiving light and a second surface 22 on which the substrate features 137 have been formed. In the illustrated configuration, the substrate features 137 have been arranged in an array on the second surface 22 of the glass substrate 90. In the illustrated configuration, the substrate features 137 each have a conical shape and are arranged in a square grid. Although one arrangement of the substrate features 137 has been illustrated, other arrangements are possible, including, for example, any of the arrangements described earlier with respect of FIGS. 4A-4H. Additionally, although the substrate features 137 are conical and have a triangular cross-section, the cross-section of the substrate features 137 can have any suitable shape, including, for example, any of the cross-sectional shapes illustrated and described earlier with reference to FIGS. 6A-6D.

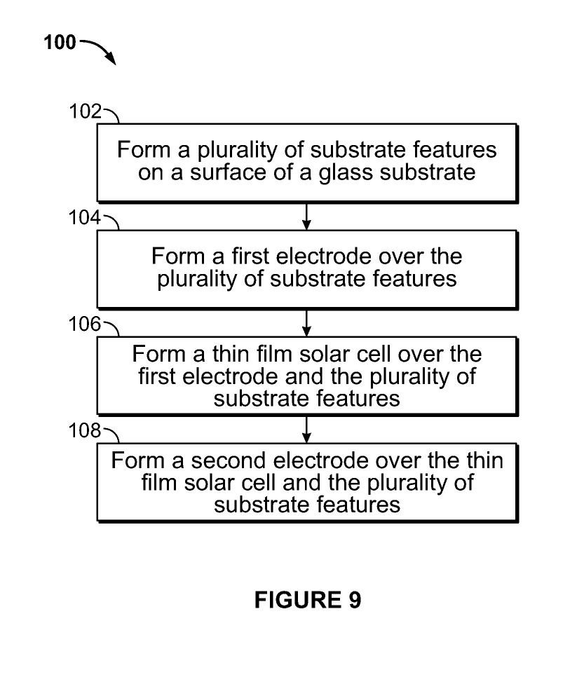

FIG. 9 shows an example of a flow diagram illustrating a manufacturing process for a photovoltaic device.

In block 102, a plurality of substrate features are formed on a surface of a glass substrate. In some implementations, the substrate features can each have a depth selected to be in the range of about 10 μm to about 1000 μm and a width in the range of about 10 μm to about 1000 μm. The substrate features can have a variety of shapes when viewed from above the glass substrate, such as shapes that are circular, elliptical, hexagonal, rectangular and/or square. In some configurations, the substrate features are arranged in an ordered pattern, such as in an array, while in other configurations the substrate features are unordered.

In some implementations, the substrate features are formed using a through-glass via process, such as a sand blasting process, a chemical etching process, and/or a laser blasting process. In certain configurations, the substrate features do not extend through the glass substrate, and can be formed using a through-glass via process in which blasting or etching associated with the substrate features is stopped before through-glass via structures are formed. In other implementations, through-glass vias are formed in a first glass layer, and a second glass layer is provided adjacent the first glass layer to form a multi-layer glass substrate.

The process 100 continues at a block 104, in which a first electrode is formed over the plurality of substrate features. In some implementations, the first electrode can include a transparent conductor, including, for example, a TCO, such as SnO₂, zinc oxide ZnO, and/or indium tin oxide ITO.

In some implementations, the glass substrate is roughened before forming the first electrode or the surface of the first electrode is roughened. For example, the surface of the glass substrate can be roughened using dry etching, wet etching, and/or sand blasting to include features having a height dimension in the range of about 1 nm to about 100 nm. In some implementations, the first electrode is roughened, such as by forming the first electrode using a CVD deposition and/or by etching or blasting the first electrode.

In an ensuing block 106, a thin film solar cell is formed over the first electrode and the plurality of substrate features. In some implementations, the solar cell includes at least one of a-Si, copper indium gallium selenide (CuInₓGa₁₋ₓSe₂), CdS, and CdTe.

The process 100 continues at a block 108, in which a second electrode is formed over the thin film solar cell and the plurality of substrate features. In some implementations the second electrode can include a reflective layer, such as aluminum (Al) or silver (Ag).

The method is illustrated as ending at block 108, however, other subsequent processes may also be performed.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that any described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A photovoltaic device comprising:
a substrate including a first surface configured to receive light and a second surface opposite the first surface, the substrate including
a first plurality of substrate features formed on the second surface of the substrate, the first plurality of features having a depth dimension in the range of about 10 μm to about 1000 μm and a width dimension in the range of about 10 μm to about 1000 μm;
a first electrode formed on the first plurality of substrate features;
a thin film solar cell disposed on the first electrode layer; and
a second electrode formed on the thin film solar cell,
wherein at least a portion of the shape of the first electrode, the thin film solar cell, and the second electrode conform to the shape of the first plurality of substrate features.

2. The photovoltaic device of claim 1, wherein the second surface of the substrate includes a second plurality of substrate features having a width dimension in the range of about 1 nm to about 100 nm and a depth dimension of about 1 to about 100 nm.

3. The photovoltaic device of claim 1, wherein the first plurality of substrate features have a slope in the range of about 20 degrees to about 70 degrees relative to a plane defined by the first surface of the substrate.

4. The photovoltaic device of claim 1, wherein the shape of the second electrode at least partially conforming to the shape of the first plurality of substrate features such that at least a portion of incident light that reflects from the second electrode propagates through the thin film solar cell at least twice.

5. The photovoltaic device of claim 1, wherein the plurality of substrate features are arranged in an ordered pattern.

6. The photovoltaic device of claim 5, wherein the ordered pattern of substrate features has a pitch in the range of about 10 μm to about 1000 μm.

7. The photovoltaic device of claim 1, wherein the first electrode includes a transparent conductive oxide (TCO) layer and the second electrode is reflective.

8. The photovoltaic device of claim 1, wherein the substrate includes a glass substrate and the first plurality of substrate features include partially formed through-glass vias.

9. The photovoltaic device of claim 1, wherein the substrate includes a first glass layer and a second glass layer adjacent the first glass layer, wherein a first surface of the first glass layer defines the first surface of the substrate and a first surface of the second glass layer defines the second surface of the substrate, and wherein a second surface of the first glass layer faces a second surface of the second glass layer, and wherein the first plurality of substrate features include through-glass vias extending from the second surface of the substrate through the second glass layer.

10. The photovoltaic device of claim 1, wherein the thin film solar cell includes at least one of amorphous silicon (a-Si), cadmium telluride (CdTe) thin film solar cell, and copper indium gallium diselenide (CIGS).

11. The photovoltaic device of claim 1, wherein the thickness of the thin film solar cell is in the range of about 0.1 μm to about 10 μm.

12. The photovoltaic device of claim 1, wherein the substrate includes glass, plastic, or acrylic.

13. A photovoltaic device comprising:
a substrate including a first surface configured to receive light and a second surface opposite the first surface, wherein the substrate includes first means for reflecting light formed on the second surface, the first reflecting means having a depth dimension in the range of 10 μm to 1000 μm and a width dimension in the range of 10 μm to 1000 μm;
a first electrode formed on the first reflecting means;
a thin film solar cell disposed on the first electrode layer; and
a second electrode formed on the thin film solar cell,
wherein at least a portion of the first electrode, the thin film solar cell, and the second electrode conform to the shape of the first plurality of substrate features.

14. The photovoltaic device of claim 13, wherein the second surface of the substrate includes second means for reflecting light having a width dimension in the range of about 1 nm to about 100 nm and a depth dimension of about 1 nm to about 100 nm.

15. The photovoltaic device of claim 13, wherein the first reflecting means is arranged in an array having a pitch in the range of about 10 μm to about 1000 μm.

16. The photovoltaic device of claim 13, wherein the first electrode includes a transparent conductive oxide (TCO) layer and the second electrode is reflective.

17. The photovoltaic device of claim 13, wherein the substrate includes a first glass layer and a second glass layer adjacent the first glass layer, wherein a first surface of the first glass layer defines the first surface of the substrate and a first surface of the second glass layer defines the second surface of the substrate, and wherein a second surface of the first glass layer faces a second surface of the second glass layer, and wherein the second reflecting means includes through-glass vias extending from the second surface of the substrate through the second glass layer.

18. A method of forming a photovoltaic device, the method comprising:
forming a plurality of substrate features on a surface of a glass substrate, the substrate features having a depth dimension in the range of about 10 μm to about 1000 μm and a width dimension in the range of about 10 μm to about 1000 μm; and
forming a thin film solar cell over the surface of the glass substrate including over the plurality of substrate features.

19. The method of claim 18, wherein forming the plurality of substrate features includes etching the plurality of substrate features into the substrate using sand blasting.

20. The method of claim 18, wherein forming the plurality of substrate features includes drilling the plurality of substrate features using a laser.

21. The method of claim 18, wherein forming the plurality of substrate features includes partially forming through-glass vias.

22. The method of claim 18, wherein the glass substrate comprises a first glass layer and a second glass layer adjacent the first glass layer, wherein a first surface of the first glass layer defines the surface of the glass substrate and a second surface of the first glass layer faces the second glass layer, and wherein forming the plurality of substrate features includes forming through-glass vias through the first glass layer.
